(19) United States
(12) Patent Application Publication
(10) Pub. No.: US 2014/0261651 A1
(43) Pub. Date: Sep. 18, 2014

(54) PV Device with Graded Grain Size and S:Se Ratio

(71) Applicant: Nanoco Technologies, Ltd., Manchester (GB)

(72) Inventor: Stephen Whitelegg, Stockport (GB)

(73) Assignee: Nanoco Technologies, Ltd., Manchester (GB)

(21) Appl. No.: 14/213,600

(22) Filed: Mar. 14, 2014

Related U.S. Application Data
(60) Provisional application No. 61/798,068, filed on Mar. 15, 2013.

(51) Int. Cl. H01L 31/065; H01L 31/0296; H01L 31/18

(52) U.S. Cl. CPC H01L 31/065; H01L 31/1828; H01L 31/0296
USPC 136/255; 438/95

(57) ABSTRACT

Disclosed herein are CIGS-based photon-absorbing layers disposed on a substrate. The photon-absorbing layers are useful in photovoltaic devices. The photon absorbing-layer is made of a semiconductor material having empirical formula AB₁₋ₓB′ₓC_{2-y}C′_{y}, where A is Cu, Zn, Ag or Cd; B and B′ are independently Al, In or Ga; C and C′ are independently S, or Se, and wherein 0≦x≦1; and 0≦y≦2. The grain size of the semiconductor material and the composition of the semiconductor material both vary as a function of depth across the layer. The layers described herein exhibit improved photovoltaic properties, including increased shunt resistance and decreased backside charge carrier recombination.

### FIELD OF THE INVENTION

The present invention relates to processes for making CIGS photovoltaic (PV) devices.

### BACKGROUND

The world demand for power now exceeds 15 TW, with the vast majority of that demand being met by the consumption of fossil fuels in the form of oil (5.3 TW), coal (4.2 TW) and natural gas (3.5 TW). Currently, solar supplies only 0.004 TW and yet the earth receives in excess 120,000 TW of power from the sun each day, which means that the earth's power demands could be met by covering 0.125% of the earth's surface with solar cells with an efficiency of only 10%.

For widespread acceptance, photovoltaic cells (“PV cells,” aka. solar cells) typically need to produce electricity at a cost that competes with that of fossil fuels. In order to lower these costs, solar cells preferably have low materials and fabrications costs coupled with increased light-to-electric conversion efficiency.

Of the various materials studied as potential candidates for use as absorbers in the next generation of solar cells, chalcopyrite-based materials (Cu(In &/or Ga)(Se &, optionally S)₂, referred to herein generically as “CIGS”) have shown great promise and have received considerable interest. The band gaps of CuInS₂ (1.5 eV) and CuInSe₂ (1.1 eV) are well matched to the solar spectrum; hence photovoltaic devices based on these materials can be efficient.

Current fabrication methods of CIGS thin film solar cells involve costly evaporation techniques, hindering their mass-market adoption. As the demand for cleaner energy increases, it is an imperative that new forms of low cost solar energy be found. To meet that demand and to address the high energy and high cost of vapor deposition, which is currently used in the production of solar cells, a range of novel copper, indium, gallium and selenium (CIS, CGS and CIGS) containing nanoparticles of varying composition have been developed that can be used to manufacture low cost solar cells with good efficiencies.

A lower cost solution to those conventional techniques is to form thin films by depositing particles of CIGS materials onto a substrate using solution-phase deposition techniques and then melting or fusing the particles into a thin film such that the particles coalesce to form large-grained thin films. To form thin semiconductor films using CIGS-type particles (i.e., CIGS or similar materials), the CIGS-type particles preferably possess certain properties that allow them to form large grained thin films. The particles are preferably small. Smaller particles typically pack more closely, which promotes the coalescence of the particles upon melting. Also, a narrow size distribution is important. The melting point of the particles is related to the particle size and a narrow size distribution promotes a uniform melting temperature, yielding an even, high quality (even distribution, good electrical properties) film.

CIGS-based nanoparticles are promising candidates for use in solution-based synthesis of CIGS semiconductor layers. Such nanoparticles are typically on the order of a few nanometers in size and can be made with a high degree of monodispersity.

These CIGS nanoparticles can be synthesized from the ‘ground up’ with the desired elemental ratios or stoichiometry to meet specific needs. The nanoparticles can be printed onto a substrate using a wide range of well-understood printing techniques or roll-to-roll processes. In some cases it is necessary to modify the surface of the semiconductor nanoparticles with an organic ligand (referred to herein as a capping agent) to make them compatible with a solvent or ink that is used to deposit the particles on a substrate. Once printed, the nanoparticles are heated to remove the organic capping agent, which destroys the quantum confinement associated with the nanoparticles and provides for a p-type semiconductor film possessing the desired crystalline structure.

However, there is room to improve the methods and materials for using CIGS-based nanoparticles to form absorber layers for PV applications. For example, backside recombination reduces the short-circuit current density (Jsc) and open circuit voltage (Voc). Moreover, thin PV films can exhibit low shunt resistance, resulting in a suppression of the Voc. Current films require thick absorber layers (>2 um) and excess material to overcome these deficiencies, despite most of the photon absorption occurring in the first 1 um if CIGS layer. There is thus a need for processes that improve the performance of PV films made using CIGS-based nanoparticles.

### SUMMARY

The disclosure provides CIGS-based absorber layers overcoming one or more deficiencies discussed above. Disclosed herein is a CIGS-based photon-absorbing layer disposed on a substrate, such as a molybdenum substrate. The photon absorbing layer is made of a semiconductor material having empirical formula AB₁₋ₓB′ₓC_{2-y}C′_{y}, where A is Cu, Zn, Ag or Cd; B and B′ are independently Al, In or Ga; C and C′ are independently S, or Se, and wherein 0≦x≦1; and 0≦y≦2. The photon-absorbing layer includes at least one sulphur-rich region and at least one-sulphur poor region. Typically the region of the absorber layer nearest the substrate is rich in sulphur, though other regions may be rich in sulphur also. For example, the S:Se ratio may increase as a function of depth across the absorber layer, having a minimum S:Se at the surface most distant from the substrate and the maximum S:Se near the substrate. Alternatively, the S:Se ratio may be large at the surface most distant from the substrate, be minimal in the middle of the absorber layer and again be large near the substrate.

Also, the grains of semiconductor material near the surface distant from the substrate are larger than the grains near the surface near the substrate. Typically, the grains distant from the substrate are at least ten times the size of the grains near the substrate.

Methods of making such absorber layers are also disclosed. The disclosed absorber layers have improved photovoltaic properties, including increased shunt resistance (rₛₕ) and minimal backside charge carrier recombination.

### DESCRIPTION OF THE DRAWINGS

FIG. 1 illustrates components a PV device.

FIG. 2 illustrates the Se:S concentration gradient in a single graded absorber layer.

FIG. 3 illustrates the grain size gradient in a single graded absorber layer prepared as described herein.

FIG. 4 illustrates the Se:S concentration gradient in a double graded PV device.

FIG. 5 illustrates the grain size gradient in a double graded absorber layer prepared as described herein.

FIG. 6 is a SEM micrograph of a CuInSSe PV device. The CuInSSe layer show large crystals in the top layer and small crystals in the bottom layer.

FIG. 7 shows Current-Voltage characteristic of a graded PV cell prepared as described herein.

### DESCRIPTION

As used herein, “CIGS,” and “CIGS-type” are used interchangeably and each refer to materials represented by the formula AB₁₋ₓB′ₓC_{2-y}C′_{y}, where A is Cu, Zn, Ag or Cd; B and B′ are independently Al, In or Ga; C and C′ are independently S, Se or Te, 0≦x≦1; and 0≦y≦2. Example materials include CuInSe₂; CuInₓGa₁₋ₓSe₂; CuGaSe₂; ZnInSe₂; ZnInₓGa₁₋ₓSe₂; ZnGa₂Se₂; AgInSe₂; AgInₓGa₁₋ₓSe₂; AgGaSe₂; CuInSe_{2-y}S_{y}; CuInₓGa₁₋ₓSe_{2-y}S_{y}; CuGaSe_{2-y}S_{y}; ZnInSe_{2-y}S_{y}; ZnInₓGa₁₋ₓSe_{2-y}S_{y}; ZnGaSe_{2-y}S_{y}; AgInSe_{2-y}S_{y}; AgInₓGa₁₋ₓSe_{2-y}S_{y}; and AgGaSe_{2-y}S_{y}, where ≦x≦1; and 0≦y≦2.

FIG. 1 is a schematic illustration of the layers of an exemplary PV device 100 based on a CIGS absorbing layer. The exemplary layers are disposed on a support 101. The layers are: a substrate layer 102 (typically molybdenum), a CIGS absorbing layer 103, a cadmium sulfide layer 104, an aluminum zinc oxide layer 105, and an aluminum contact layer 106. One of skill in the art will appreciate that a CIGS-based PV device may include more or fewer layers than are illustrate in FIG. 1.

Support 101 can be essentially any type of rigid or semi-rigid material capable of supporting layers 102-106. Examples include glass, silicon, and rollable materials such as plastics. Substrate layer 102 is disposed on support layer 101 to provide electrical contact to the PV device and to promote adhesion of CIGS absorption layer 103 to the support layer. Molybdenum has been found to be particularly suitable as a substrate layer 102.

The molybdenum substrate is typically prepared using a sputtering technique, for example, bombarding a molybdenum source with argon ions to sputter molybdenum onto a target (such as support 101). The density of the resulting molybdenum film can be adjusted by increasing or decreasing the processing pressure of the Ar sputter gas. At higher Ar pressures (>10 mTorr) collisions of the sputtered Mo atoms with the process gas reduce the energy of the Mo atoms, thereby increasing the mean free path and increasing the angle at which the Mo atoms impact the target. This leads to a build-up of tensile forces, which increases the porosity and intergranular spacing of the resulting Mo film. Decreasing the Ar pressure causes the resulting Mo film to become less porous and more tightly packed. As the Ar pressure is decreased further, compressive forces take over after the tensile stress reaches a maximum. High-density films prepared in this manner have been observed to have low resistivity (<1×10⁻⁴ Ω-cm), but strain in the films causes them to have poor adhesion to the support/target.

CIGS absorbing layer 103 is can include one or more layers of Cu, In and/or Ga, Se and/or S. CIGS absorbing layer may be of a uniform stoichiometry throughout the layer or, alternatively, the stoichiometry of the Cu, In and/or Ga, Se and/or S may vary throughout the layer. According to one embodiment, the ratio of In to Ga can vary as a function of depth within the layer. Likewise, the ratio of Se to S may vary within the layer.

According to the embodiment illustrated in FIG. 1, CIGS absorbing layer 103 is a p-type semiconductor. It may therefore be advantageous to include a layer of n-type semiconductor 104 within PV cell 100. Examples of suitable n-type semiconductors include CdS.

Top electrode 105 is preferably a transparent conductor, such as indium tin oxide (ITO) or aluminum zinc oxide (AZO). Contact with top electrode 105 can be provided by a metal contact 106, which can be essentially any metal, such as aluminum, nickel, or alloys thereof, for example.

Methods of depositing CIGS layers on a substrate are described in U.S. patent application Ser. No. 12/324,354, filed Nov. 26, 2008, and published as Pub. No. US2009/0139574, and in U.S. Pat. No. 8,563,348, issued Oct. 22, 2013, the entire contents of both of which are incorporated herein by reference. Briefly, CIGS layers can be formed on a substrate by dispersing CIGS-type nanoparticles in an ink composition and using the ink composition to form a film on the substrate. The CIGS material used in the ink composition is generally nanoparticles represented by the formula AB₁₋ₓB′ₓSe_{2-y}C_{y}, where A is Cu, Zn, Ag or Cd; B and B′ are independently Al, In or Ga; C is S or Te, 0≦x≦1; and 0≦y≦2 (note that if >0, then B′ B). Typically, A is Cu, B and B′ are In or Ga, and C is S.

Following the deposition of one or more layers of CIGS films, the film is then annealed to yield a layer of CIGS material. U.S. Patent Publication No. 2009/0139574 describes annealing under both static and dynamic inert atmospheres, such as nitrogen. However, reactive atmospheres can also be used for annealing the CIGS films. For example, Se tends to be ejected from films during annealing. Se-containing films may therefore be annealed under a Se-containing atmosphere, such as H₂Se, to maintain or adjust the concentration of Se in the film.

Also, Se can replace S in films during annealing by annealing S-containing films under a Se-containing atmosphere. In other words, the nanoparticles in the ink are of a first material having formula AB₁₋ₓB′ₓSe_{2-y}C_{y} and the resulting layer is treated, using reactive annealing, to convert the layer to a different material having a different formula according to AB₁₋ₓB′ₓSe_{2-y}C_{y}. For example, the nanoparticles may be of the formula CuInS₂, and the resulting layer of CuInS₂ can be treated with gaseous Se to replace some of the sulfur with selenium, yielding a layer of CuInSe_{2-y}S_{y}. It has been found that use of a Se-containing atmosphere to anneal S-containing films aids the formation of large grains in the film because the volume of the film expands when Se replaces S atoms. The extent of volume expansion is about 14%.

Replacement of S with Se in a CuIn[Ga]S nanoparticle films by heating in a selenium rich atmosphere leads to a gradient of Se:S ratio as a function of depth within the film. The relative S concentration increasing and the Se concentration decreases as a function of depth (i.e., towards the Mo electrode) because, during annealing, the Se must diffuse through the film in order to replace the S. Such a gradient is illustrated in FIG. 2. Absorber films having a gradient as illustrated in FIG. 2, i.e., where the relative amount of Se decreases as a function of depth, are termed single graded structures. Note that FIG. 2 is drawn as a linear function for representation purposes only; the function need not be linear. It has been found that introducing a single graded relationship in the Se:S ratio, as a function of depth, reduces back side recombination within the absorber layer. This is in part because the composition gradient introduces a gradient in the band gap of the material. The S-rich material has a higher band gap; thus, the band gap of the film increases towards the Mo electrode. The increased band gap near the Mo electrode can be thought of as “reflecting” the electrons that would otherwise contribute to backside recombination.

Sintering the sulphur-containing material in the presence of Se atmosphere can also induce crystal growth and densification as the replacement of the S with Se results in an expansion in the crystal's unit cell. Therefore the grain size also decreases as a function of depth, as illustrated in FIG. 3. Generally, it is thought to be desirable to maximize grain growth because doing so minimized grain boundaries. Grain boundaries generally impede carrier mobility within the material. However, it has been found that smaller conductive crystals near the Mo electrode increase the shunt resistance (rₛₕ) of the cell, increasing the fill factor (FF) of the cell.

Both Se:S gradient and grain size gradient can be controlled by anneal time, anneal temperature, precursor particle stoichiometry, and annealing gas composition (i.e., the annealing atmosphere may be made Se rich). Control over both crystal size and band gap, as a function of depth within the CIGS absorber layer, as described herein, is a powerful tool for producing highly efficient solar cells. The methods disclosed herein allow devices with large grains throughout the bulk of the absorber layer, which provide fewer grain boundaries and, thus, high carrier mobility. However, smaller, more densely packed grains near the Mo electrode provide increased rₛₕ. Moreover, the higher band gap material (i.e., the S-rich material) near the Mo results in decreased backside recombination. Each of those factors contribute to increasing the performance of the solar cell.

Generally, the grain size profile across the cell correlates with the Se concentration following reactive annealing. FIG. 6 shows an SEM image of an absorber layer prepared as described in the Examples, below. Briefly, a film prepared using CuInS₂ nanocrystals was annealed in a Se-rich atmosphere. The resulting film, post annealing, has a region 601, having very large grains, and a region 602, having small grains. The regions 601 and 602 correspond with regions of high and low Se concentrations, respectively. According to certain embodiments, the grains in the large grain region may be five or ten times the size of the grains in the small grain region. The grain size differential may be even greater than ten times.

It is possible to make notched gradients in the Se/S profile, as illustrated in FIG. 4, by using both Se and S annealing atmospheres and controlling the relative atmospheric content during the annealing process. For example, the film may first be annealed in a Se-rich atmosphere and then annealed further in a S-rich atmosphere.

Films having the Se:S profile illustrated in FIG. 4 are termed double graded structures and have reduced back side recombination and increased Voc because of the presence of higher band gap material at both edges of the absorber layer. Such structures also have higher rₛₕ due to the presence of smaller, less conductive crystals at the bottom of the absorber layer (Mo electrode interface). Somewhat surprisingly, the crystal size profile across the absorber layer remains similar to the crystal size profile observed for a single graded structure (compare FIG. 5 to FIG. 3).

The methods described herein are further exemplified in the below examples.

### EXAMPLES

A PV device, as illustrated in FIG. 1 was prepared as described below.

Mo-Glass Substrate Preparation. Molybdenum coated soda-lime glass (2.5×2.5 cm) was used as the substrate. The glass substrate was cleaned prior to Mo deposition using a detergent such as Decon®, followed by a rinse with water and further cleaning with acetone and isopropanol, followed by a UV ozone treatment. A 1000 um molybdenum was coated by RF sputtering at a pressure of 4 mT in Ar with a power of 40 W.

Coating of CuInS₂ nanoparticle layer. CuInS₂ nanoparticles were prepared essentially as described in Applicant's co-owned patent application Pub. No. 2009/0139574, referenced above. Thin films of CuInS₂ are cast onto the substrate by spin coating in a glovebox with a dry nitrogen atmosphere. The CuInS₂ film was deposited on the substrate using a multilayer technique. A total of 11 layers of CuInS₂ nanoparticles were used to fabricate a 1 um thick layer nanoparticles. The first layer was cast onto the substrate using the 100 mg/ml solution in toluene; all subsequent layers were cast using the 200 mg/ml solution.

For each layer a bead of CuInS₂ nanoparticle ink was deposited on to the substrate while stationary through a 0.2 μm PTFE filter. The substrate was then spun at 3000 rpm for 40 seconds. The sample was then transferred to a hotplate at 260° C. for 5 minutes, then transferred to a hotplate at 400° C. for 5 minutes; then transferred to a cold plate for >1 minute. The process was repeated for each CuInS₂ layer.

Reactive annealing CuInS nanoparticle layer. The 1 um CuInS₂ nanoparticle film was annealing in a H₂Se:N₂ containing atmosphere (˜5% wt H₂Se), using a tube furnace. The heating profile was ramp 10° C./min, dwell 500° C. for 60 minutes; cool down using air assisted cooling ˜5° C/min. H₂Se flow was switched on and off at 400° C. When H₂Se was off the atmosphere in the tube furnace was 100% N₂. The film was etched in a KCN solution (10% wt.) for 3 minutes. The substrate was baked in air using a hotplate at 180° C. for 10 minutes. FIG. 6 shows an SEM micrograph of the resulting device. The CuInSSe layer shows large crystal in the top layer and small crystal in the bottom layer. Depth profiling of the PV device using secondary ion mass spectrometry (SIMS) indicates that the concentration of selenium decreases as a function of depth and the concentration of sulphur increases as a function of depth. The boundary 603 between the large grain region 601 and the small grain region 602 corresponds to an inflection point of increasing sulphur concentration and decreasing selenium concentration. The concentrations of copper and indium are essentially uniform across the film.

Deposition of Additional Device Layers. A buffer layer of cadmium sulfide (approximately 70 nm thickness) was deposited on top of the absorber layer chemical bath method. A conductive window layer of aluminium-doped zinc oxide (2% wt Al) with a thickness of 600 nm was sputter coated on top of the cadmium sulfide buffer layer. The ZnO:Al layer was then patterned using a shadow mask and a conductive grid of aluminium then deposited on top of the ZnO:Al window using a shadow mask and vacuum evaporation. The active area of the final PV device was 0.2 cm².

The resulting solar cell has a ˜1 μm layer of p-type CuInSSe on a 1 um layer of molybdenum which is itself supported on a soda glass base substrate. On top of the CIGS layer is provided a thin 70 nm layer of n-type CdS upon which has been deposited a 600 nm layer of ZnO:Al (2 wt %) 7, with 200 nm Al contacts provided thereon.

Device Performance. The current/voltage characteristic of the solar cell fabricated as described above was measured under dark and light conditions. For the light conditions a Newport solar simulator was used with an AM1.5G filter. The output was callibrated to be 1030 W/m². The result is shown in FIG. 7

We claim:

1. A photovoltaic device component, comprising:
a substrate, and
a photon-absorbing layer disposed on the substrate and having a surface near the substrate and a surface distant from the substrate the photon-absorbing layer comprising grains of semiconductor material having empirical formula AB₁₋ₓB′ₓC_{2-y}C′_{y}, where A is Cu, Zn, Ag or Cd; B and B′ are independently Al, In or Ga; C and C′ are independently S, or Se, and wherein 0≦x≦1; and 0≦y≦2, wherein the photon-absorbing layer comprises at least one sulphur-rich region and at least one sulphur poor region and wherein the grains of semiconductor material near the surface distant from the substrate are larger than the grains near the surface near the substrate.

2. The component of claim 1, wherein at least one sulphur-rich region is nearer the substrate than any sulphur-poor region.

3. The component of claim 1, wherein the photon-absorbing layer comprises a first sulphur-rich region near the surface near the substrate, a second sulphur-rich region near the surface distant from the substrate, and a sulphur-poor region between the first and second sulphur-rich regions.

4. The component of claim 1, wherein the grains of semiconductor material near the surface distant from the substrate have a size at least ten times greater than the size of the semiconductor grains near the substrate.

5. The component of claim 1, wherein the grains of semiconductor material near the surface distant from the substrate have a size at least five times greater than the size of the semiconductor grains near the substrate.

6. The component of claim 1, wherein the semiconductor material near the surface near the substrate has a larger band-gap than the semiconductor material near the surface distant from the substrate.

7. The component of claim 1, wherein the substrate comprises molybdenum.

8. The component of claim 1, further comprising a transparent electrode of a material selected from the group consisting of indium tin oxide and aluminium zinc oxide.

9. The component of claim 1, wherein the grains of semiconductor material near the surface distant from the substrate are at least 200 nm in size.

10. The component of claim 1, wherein the grains of semiconductor material near the surface distant from the substrate are at least 600 nm in size.

11. A method of making a photon-absorbing layer, the method comprising:
providing a substrate and one or more ink compositions comprising nanoparticles of semiconductor material having empirical formula AB₁₋ₓB′ₓC_{2-y}C′_{y}, where A is Cu, Zn, Ag or Cd; B and B′ are independently Al, In or Ga; C and C′ are independently S, or Se, and wherein 0≦x≦1; and 0≦y≦2;
printing one or more layers of the ink composition onto the substrate;
annealing the substrate and layers of the ink composition in an atmosphere comprising selenium to form a semiconductor layer having a surface near the substrate and a surface distant from the substrate and comprising grains of the semiconductor material wherein the grains of semiconductor material near the surface distant from the substrate are larger than the grains near the surface near the substrate and wherein the semiconductor layer comprises at least one sulphur-rich region and at least one sulphur-poor region.

12. The method of claim 11, wherein at least one sulphur-rich region is nearer the substrate than any sulphur-poor region.

13. The method of claim 11, further comprising annealing the semiconductor layer in an atmosphere comprising sulphur to yield a first sulphur-rich region near the surface near the substrate, a second sulphur-rich region near the surface distant from the substrate, and a sulphur-poor region between the first and second sulphur-rich regions.

14. The method of claim 11, wherein the grains of semiconductor material near the surface distant from the substrate have a size at least ten times greater than the size of the semiconductor grains near the substrate.

15. The method of claim 11, wherein the grains of semiconductor material near the surface distant from the substrate have a size at least five times greater than the size of the semiconductor grains near the substrate.
